(19) United States
(12) Patent Application Publication
(10) Pub. No.: US 2008/0083955 A1
(43) Pub. Date: Apr. 10, 2008

(54) INTRINSICALLY STRESSED LINER AND FABRICATION METHODS THEREOF

(76) Inventors: Thomas S. Kanarsky, Hopewell Junction, NY (US); Qiqing Ouyang, Yorktown Heights, NY (US); Kathryn T. Schonenberg, Wappingers Falls, NY (US); Chun-Yung Sung, Poughkeepsie, NY (US)

Correspondence Address: HOFFMAN, WARNICK & D'ALESSANDRO LLC, 75 STATE ST, 14TH FL, ALBANY, NY, 12207, US

(21) Appl. No.: 11/538,506

(22) Filed: Oct. 4, 2006

(51) Int. Cl. H01L 29/76

(52) U.S. Cl. 257/382

(57) ABSTRACT

A stressed liner for improving carrier mobility in a transistor and a method for fabricating the same is disclosed. The stressed liner includes an intrinsically stressed conductive film encapsulated between two insulating layers such as silicon nitride, silicon oxide, or oxynitride. The stressed liner may be compressively-stressed or tensile-stressed depending on whether an n-FET or p-FET is required.

### BACKGROUND OF THE INVENTION

1. Technical Field

The invention relates generally to complimentary metal oxide semiconductor (CMOS) fabrication, and more particularly, to methods for fabricating an intrinsically stressed conductive film as a liner to improve carrier mobility in silicon (Si) CMOS.

2. Background Art

Continued CMOS scaling demands materials with enhanced carrier-channel mobility (i.e., holes and electrons are required to move more quickly). Enhanced carrier-channel mobility may be achieved by a number of silicon technologies, for example: strained silicon, silicon germanium (SiGe), silicon on insulator (SOI) or a combination thereof. Stressed liners are also widely used in the fabrication of silicon (Si) CMOS because they improve semiconductor device performance by applying stress to enhance mobility. Increased carrier mobility achieved by stressed liners can be as high as 60%. Conventional stressed liners have levels up to about 4 gigapascal (GPa).

In order to increase the stress applied to the channel, the film thickness needs to be increased. This however presents a challenge to scaling and eventually the performance gain saturates. To increase the applied stress and also permit scaling, thinner films of higher stress are needed. Most conventional liners are fabricated from nitride, like silicon nitride (Si₃N₄).

In view of the foregoing, there is a need in the art for a solution to the problems of the related art.

### SUMMARY OF THE INVENTION

A stressed liner for improving carrier mobility in a transistor and a method for fabricating the same is disclosed. The stressed liner includes an intrinsically stressed conductive film, which is encapsulated between two insulating layers. The insulating layers may be formed from material such as silicon nitride, silicon oxide, or oxynitride. The stressed liner may be compressively-stressed or tensile-stressed depending on whether an n-FET or p-FET is required.

A first aspect of the invention provides a transistor comprising: a substrate including a source region and a drain region; a gate disposed on the substrate between the source region and the drain region; a silicide layer formed in the source region, the drain region and the gate; a stressed liner disposed over the source region, the drain region and the gate, wherein the stressed liner includes a stressed conductive layer disposed between a first insulating layer and a second insulating layer; at least one conductive via extending through a third insulating layer to one of the gate, the source region and the drain region; and a barrier layer encompassing the at least one conductive via.

A second aspect of the invention provides a method comprising: forming a structure including a gate, a source region and a drain region on a substrate; forming a stressed liner over the structure, the stressed liner including a stressed conductive layer between a first insulating layer, and a second insulating layer; depositing a third insulating layer over the stressed liner; patterning and etching an opening through the third insulating layer and the stressed liner layer; and forming a contact via including a barrier layer in the opening.

The illustrative aspects of the present invention are designed to solve the problems herein described and other problems not discussed, which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 is a sectional view of an embodiment of the present invention.

FIG. 2 is a sectional view of another embodiment of the present invention.

FIG. 3 is a sectional view of third embodiment of the present invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

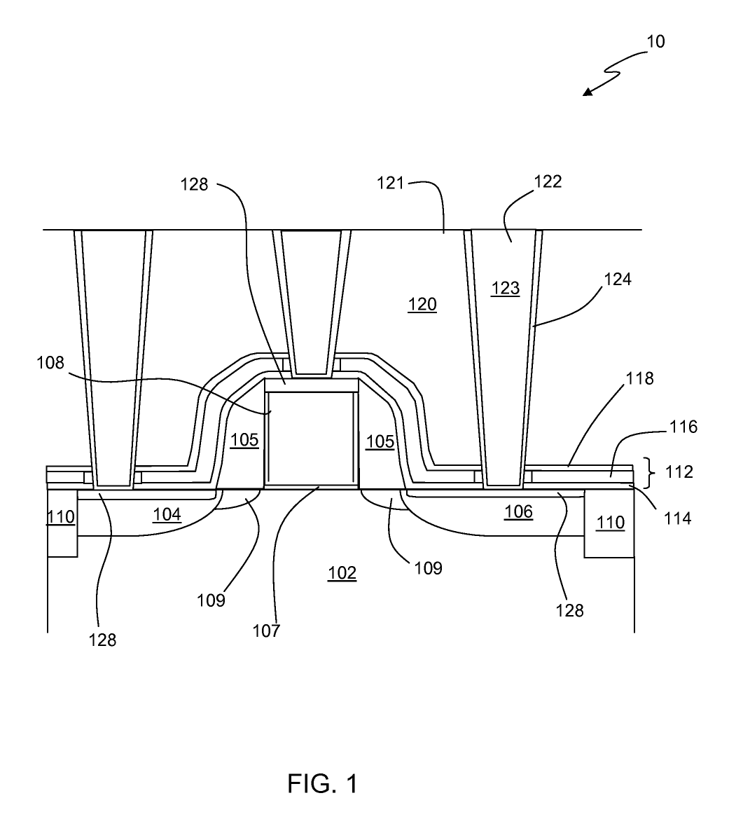

FIG. 1 illustrates a structure 10 of an embodiment of the present invention. Structure 10, may represent an n-channel field effect transistor (n-FET) or a p-channel field effect transistor (p-FET), of the many n-FETs/p-FETs integrated in an integrated circuit (not shown).

Structure 10 includes a substrate 102 with a source/drain region 104, 106. Source/drain regions 104, 106 are interchangeable and are formed by ion implantation. A gate 108 is formed on a gate dielectric 107, disposed on an area on substrate 102, located between source/drain regions 104, 106. Gate dielectric 107 may be formed from, for example but not limited to: silicon dioxide (SiO₂). Each source/drain region 104, 106 may include an extension region 109. Between each adjacent source/drain region 104, 106, a trench isolation region 110 may be provided. A silicide layer 128 is disposed in gate 108, source region 104 and drain region 106. Silicide layer 128 may be formed from using any known or later developed techniques, for example, depositing a metal such as titanium, nickel or cobalt; annealing the metal to the silicon and removing unreacted metal. A stressed liner 112 is disposed over gate 108 and source/drain regions 104, 106. Stressed liner 112 includes a stressed conductive layer 116, for example, but not limited to: a titanium nitride (TiN), tantalum nitride (TaN) and colbalt silicide (CoSi₂) layer disposed between a first insulating layer 114 and a second insulating layer 118. First and second insulating layers 114, 118 may be formed from, for example, silicon oxide (SiO₂), silicon oxynitride, silicon nitride (Si₃N₄) and any combination thereof. Stressed liner 112 has a thickness ranging from approximately 50 nm to approximately 100 nm. Stressed conductive layer 116 has a thickness ranging from approximately 20 nm to approximately 60 nm. First and second insulating layers 114, 118 each has a thickness ranging from approximately 5 nm to approximately 10 nm. Stressed liner 112 may be intrinsically compressively stressed or intrinsically tensile stressed. For example, compressively stressed liner 112 enhances hole mobility in p-FET while tensile stressed liner 112 enhances electron mobility in n-FET. The intrinsic stress in conductive layer 116, whether compressive or tensile, is mostly determined by the type of deposition method. In the case where high temperature process such as chemical vapor deposition (CVD) is applied, the resulting film which forms the conductive layer 116 is usually tensile stressed. For example, when nickel silicide (NiSi) or other conductive materials is deposited by CVD, the resulting conductive films forming conductive layer 116 is tensile stressed. When other methods such as PVD (Physical Vapor Deposition) or sputtering are applied, the resulting conductive films forming conductive layer 116 are usually compressively stressed. Examples of materials for forming intrinsically compressively stressed conductive layers include but are not limited to: titanium nitride (TiN), tantalum nitride (TaN) and cobalt silicide (CoSi₂). Taking titanium nitride (TiN) as an exemplary conductive material for forming stressed conductive layer 116, the compressive stress therein may range from approximately 8 GPa to approximately 12 GPa. First and second insulating layers 114, 118 of silicon nitride, silicon oxide or silicon oxynitride or any combination thereof may be either compressively or tensile stressed to match the stressed conductive layer 116. A third insulating layer 120 is deposited on stressed liner 112. Conductive vias 122 extend from exposed surface 121 through insulating layer 120 and terminates at silicide layer 128 above gate 108, source region 104 or drain region 106. Each conductive via 122 includes a conductive material 123 and a conductive metal diffusion barrier 124. This structure is applicable in the case of a p-FET and an n-FET.

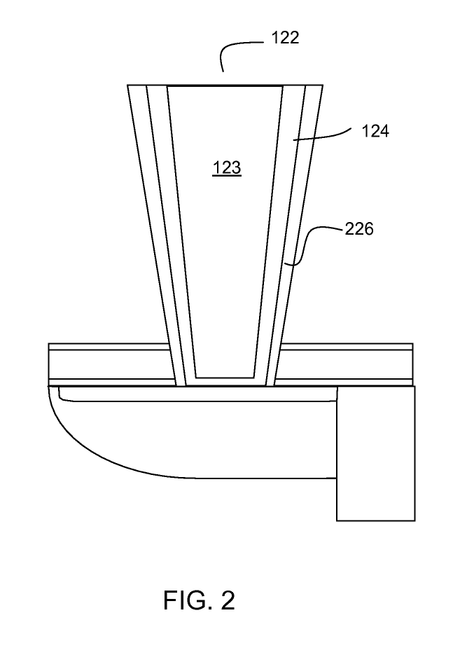

FIG. 2 illustrates another embodiment of the invention from FIG. 1 as described above. In this embodiment, via 122 includes a dielectric liner 226 in addition to diffusion barrier 124.

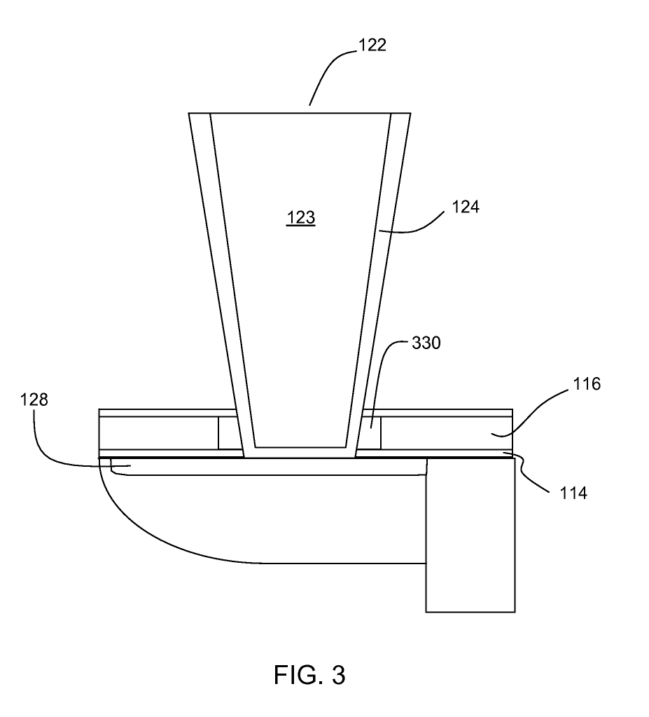

FIG. 3 illustrates an alternative embodiment of the invention from FIG. 1 as described above. In this embodiment, a dielectric seal 330 buffers stressed conductive layer 116 from diffusion barrier 124 of via 122.

The fabrication of embodiments illustrated in FIG. 1, FIG. 2 and FIG. 3 is discussed hereon. As illustrated in FIG. 1, substrate 102 includes a gate 108, a source region 104 and drain region 106. Substrate 102 may be formed from materials including but not limited to: silicon, germanium, silicon germanium and silicon carbide. Trench isolation region 110 is formed on substrate 102 by applying current shallow trench isolation (STI) techniques or later developed methods. Adjacent to trench isolation regions 110 are formed source/drain regions 104, 106 with extensions 109 by ion implantation. Above the extensions are spacers 105 on either side of gate 108. Below gate 108 is gate dielectric 107, which may be formed using present or later developed methods with material including but not limited to: silicon oxide (SiO₂), silicon nitride (Si₃N₄), silicon oxynitride (SiON), hafnium oxide (HfO₂), hafnium silicate (HfSiO₄), zirconium silicate (ZrO₂), zirconium oxide (ZrO₂), high-k material or any combination thereof. Silicide layer 128 is formed over gate 108, source region 104, and drain region 106 by known deposition techniques, for example, chemical vapor deposition (CVD), low pressure CVD (LPCVD), plasma-enhanced CVD (PECVD), semi-atmosphere CVD (SACVD) high density plasma CVD (HDPCVD), or later known techniques. Following formation of silicide layer 128 is the formation of stressed liner 112 which involves the deposition of first insulating layer 114 such as silicon nitride (Si₃N₄), silicon oxide (SiO₂), or silicon oxynitride (SiON) and any combination thereof, followed by deposition of stressed conductive layer 116 such as titanium nitride (TiN) and second insulating layer 118 such as silicon nitride (Si₃N₄), silicon oxide (SiO₂), or silicon oxynitride (SiON) and any combination thereof. Deposition of a third insulating layer 120 follows using currently known deposition techniques or later developed techniques. Insulating material for forming third insulating layer 120 may include but is not limited to: silicon nitride (Si₃N₄), silicon oxide (SiO₂), fluorinated silicon oxide (FSG), hydrogenated silicon oxycarbide (SiCOH) and porous hydrogenated silicon oxycarbide. An etching step follows to form an opening in insulating layer 120 through stressed liner 112 by applying known lithographic and etching methods or other later know/developed methods. The opening extends from surface 121 through insulating material 120, stressed liner 112 to silicide layer 128 without etching through silicide layer 128. The opening is then lined with a diffusion barrier 124 of material including but not limited to, for example, titanium nitride (TiN) or silicon nitride (SiN). Each via 122 provides a conducting path from surface 121 through insulating material 120 to gate 108, source region 104 and drain region 106. A further deposition step, forms conductive metal diffusion barrier 124 in the opening. A contact via 122 is formed in the opening by filling the opening with a conductive material 123. Materials for conductive metal diffusion barrier 124 may include, for example, titanium nitride (TiN) or any other typical diffusion barrier material. Conductive material 123 to fill via 122 may be a metal including but not limited to: copper (Cu), tungsten (W) and ruthenium (Ru).

From the fabrication process described above, an additional step may be introduced to deposit a dielectric liner layer 226 (FIG. 2) before the deposition of diffusion barrier 124 and conductive material 123 as shown in FIG. 2. For example, dielectric liner layer 226 may be deposited after a cleaning step following a reactive ion etching (RIE).

The following process may replace the process steps described in accordance to FIG. 2 for forming the embodiment illustrated in FIG. 3. Instead of the cleaning step after the RIE, stressed conductive layer 116 is wet etched to form a recess (not shown) terminating at first insulating layer 114, which serves as bottom of the recess. A dielectric seal 330 like silicon nitride (Si₃N₄) is deposited in the recess. Continuing with RIE opens a portion of the dielectric seal 330 which allows opening through to terminate at silicide layer 128. Following completion of RIE and cleaning, deposition of conductive metal diffusion barrier 124 and conductive material 123 takes place as described above. Since titanium nitride possesses conductive capabilities, dielectric seal 330 prevents conduction from conductive material 123 in via 122 through conductive metal diffusion barrier 124 into stressed conductive layer 116.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A transistor comprising:
a substrate including a source region and a drain region;
a gate disposed on the substrate between the source region and the drain region;
a silicide layer formed in the source region, the drain region and the gate;
a stressed liner disposed over the source region, the drain region and the gate, wherein the stressed liner includes a stressed conductive layer disposed between a first insulating layer and a second insulating layer;
at least one conductive via extending through a third insulating layer to one of the gate, the source region and the drain region; and
a barrier layer encompassing the at least one conductive via.

2. The transistor of claim 1, wherein the at least one conductive via includes a dielectric liner.

3. The transistor of claim 1, wherein the stressed conductive layer includes a dielectric seal through which the at least one conductive via extends.

4. The transistor of claim 1, wherein the stressed conductive layer comprises of at least one stressed conductive film.

5. The transistor of claim 4, wherein the at least one stressed conductive film is selected from a group of compressively stressed films consisting of: titanium nitride (TiN), tantalum nitride (TaN) and cobalt silicide (CoSi₂), in the case that the transistor is a pFET.

6. The transistor of claim 4, wherein the at least one stressed conductive film is tensile stressed nickel silicide (NiSi) in the case that the transistor is an nFET.

7. The transistor of claim 5, wherein a stressed titanium nitride conductive layer has a compressive stress ranging from approximately 8 GPa to approximately 12 GPa.

8. The transistor of claim 1, wherein the first and second insulating layers are formed from an insulating material selected from a group consisting of: a silicon oxide, a silicon nitride, a silicon oxynitride and any combination thereof.

9. The transistor of claim 1, wherein the first and second insulating layers are compressively stressed in the case that the transistor is a pFET and tensile stressed in the case that the transistor is an nFET.

10. A method comprising:
forming a structure including a gate, a source region and a drain region on a substrate;
forming a stressed liner over the structure, the stressed liner including a stressed conductive layer between a first insulating layer, and a second insulating layer;
depositing a third insulating layer over the stressed liner;
patterning and etching an opening through the third insulating layer and the stressed liner layer; and
forming a contact via including a barrier layer in the opening.

11. The method according to claim 10, further includes depositing a dielectric liner layer in the opening.

12. The method according to claim 10, further includes etching a portion of the stressed conductive layer to form a recess, depositing a dielectric material to fill the recess, and etching the dielectric material to form a seal, wherein the opening etching extends through the dielectric material.

13. The method according to claim 10, wherein the conductive layer includes at least one compressively stressed conductive film in the case that the transistor is a p-FET.

14. The method according to claim 10, wherein the conductive layer includes at least one tensile stressed conductive film in the case that the transistor is an n-FET.

15. The method according to clam 10, wherein the first and second insulating layers are formed from an insulating material selected from a group consisting of: a silicon oxide, a silicon nitride, a silicon oxynitride and any combination thereof.

16. The method according to claim 10, wherein the first and second insulating layers are compressively stressed in the case that the transistor is a pFET and tensile stressed in the case that the transistor is an nFET.
